(19) United States
(12) Patent Application Publication
(10) Pub. No.: US 2014/0007917 A1
(43) Pub. Date: Jan. 9, 2014

(54) THREE-DIMENSIONAL RINGED SOLAR ARRAY

(71) Applicant: Vincent Jade Lin, Richmond Hill, NY (US)

(72) Inventor: Vincent Jade Lin, Richmond Hill, NY (US)

(21) Appl. No.: 13/541,161

(22) Filed: Jul. 3, 2012

(51) Int. Cl. H01L 31/042

(52) U.S. Cl. 136/244

(57) ABSTRACT

An array comprising a first photovoltaic module, with a second photovoltaic module placed at a distance above the first. Wherein the second photovoltaic module comprises a central hole or cutout. The second photovoltaic module may be in the shape of a ring. A plurality of the second photovoltaic module may be arranged at a distance above each other so that they are overlapping.

The solar array provided herein provides a more cost effective solution in design and implementation compared to traditional arrays.

### FIELD OF THE INVENTION

The present invention relates to three-dimensional solar arrays of photovoltaic modules.

### BACKGROUND

Traditional solar arrays are at the present time two-dimensional. Often, traditional quadrilateral photovoltaic modules are connected seamlessly to create a large quadrilateral shaped solar array. One limitation of two-dimensional arrays is that the power they can generate is limited to the available space that they may be placed upon. Horizontal examples include a piece of land and a rooftop. Vertical examples include the wall face of a building, pole, or mountain. Whether horizontal or vertical, it is often the amount of space available that determines the amount of power generated.

One of the limitations of reliance on space is that some times, the amount of space available for the placement of a solar array is insufficient to generate a desired amount of electrical power, which results in possibly looking for other ways to power electrical generational needs.

A second limitation of two-dimensional arrays relying on space is that sometimes the cost of the space can add to the overall calculation of price. A square meter with the purchase price of one hundred dollars is vastly different from another square meter with the purchase price of one thousand dollars, let alone tens of thousands dollars or more.

Often solar power generation and the use of that power are most efficient when the place of electrical consumption and use is near to the place of power generation. For this reason, the most efficient way to use solar power in large cities, is to generate that power in the cities themselves, and not some far away location. But because of the nature of two-dimensional solar arrays that limit the amount of power generation to the amount of space available, solar arrays placed in large cities face an issue of finding enough space and sometimes must also consider the financial price of using that space. This limits large-scale usage of solar arrays in large cities.

Attempts to go beyond the power generation capabilities of two-dimensional arrays have been attempted by means of solar trackers, vertical two-dimensional arrays, and three-dimensional frames.

Solar trackers are an attempt to boost the efficiency of power generated by two-dimensional arrays by continually moving and positioning those arrays to face the sun's trajectory in the sky as it moves from sunrise to sunset. The solar trackers represent a desire to maximize the amount of solar energy generation per square meter of land or space. The cost effectiveness of solar trackers have sometimes been questioned, because the amount of benefit in electrical generation that they provide have sometimes been less than the electrical benefit of buying additional photovoltaic modules. Add to this the maintenance cost of maintaining these moving, weather sensitive solar trackers placed upon poles that can be affected by strong winds and other forms of weather, and the electrical benefit and financial cost of that benefit, comes further into question.

Another attempt to go beyond available land space is to use vertical two-dimensional arrays, represented in solar arrays placed on the wall of buildings, poles, or mountains.

In patent number: U.S. Pat. No. 6,060,658A, a pole with photovoltaic modules placed on multiple sides provides a means to place photovoltaic modules vertically so that they are facing outwards from the center. The overall premise is that by adding multiple photovoltaic modules in all directions, more solar energy will be generated even if certain photovoltaic modules generate a fraction of their true output because of facing the opposite direction of the sun. By increasing the number of photovoltaic modules placed in all directions the overall cost has increased, and a bit more energy captured, but the overall efficiency in solar power generation is reduced.

An attempt at a three-dimensional array is represented in patent number: US20110056540A1. The title of the patent is “THREE-DIMENSIONAL SOLAR ARRAYS”. The photovoltaic modules of this array are placed on different elevations, thus creating a three-dimensional frame, but a three-dimensional frame and a three-dimensional array are not exactly the same thing. The limitation of this system is that photovoltaic modules cannot be placed directly above each other. In the abstract section of mentioned array, it says “wherein the photovoltaic modules are arranged and retained in the positions of successive grid layers in a substantially non-overlapping vertical relationship so that none of the photovoltaic modules in any grid layer substantially vertically occludes any other of the photovoltaic modules in any other grid layer”.

Even though the title of the array contains the word “THREE-DIMENSIONAL”, it lacks the ability to place a single photovoltaic module directly above another photovoltaic module, let alone multiple levels of photovoltaic modules placed above a base photovoltaic module.

### SUMMARY OF THE INVENTION

Accordingly, several objects and advantages of the present invention are to provide a means for three-dimensional arrangement of photovoltaic modules so that the amount of electricity that can be generated can exceed the normal limitations of two-dimensional arrays. This allows more electrical generation per square area of land, per square area on a building's rooftop, or for devices or vehicles that incorporate solar absorption as a means of generating electricity.

Another advantage of the present invention is to provide a means to efficiently reabsorb energy that is used by a light bulb to create light. When a light bulb creates light from the initial energy generated from sunlight, it illuminates the solar array below it. When the light bulb is positioned and shining above the ringed photovoltaic modules, a percentage of electrical energy is reabsorbed. This allows the reabsorbed energy to further power the same light bulb that is emitting the light.

A further advantage is to provide a means of linking photovoltaic modules by means of a central pole or hollow pole so as to allow the hollow pole to be placed upon a means of rotation. This allows for three hundred sixty degrees of rotation. In addition, poles or hollow poles that pass through the central pole or hollow pole, link ringed photovoltaic modules to the central pole or hollow pole. The rotation of these poles or hollow poles allows the ringed photovoltaic modules linked to them to rotate to face different vertical elevations so that they may match the elevation of the sun in the sky. The ability to rotate three hundred sixty degrees at the base, and the ability for the ringed photovoltaic modules to rotate to match different elevations allows for this means of linking to be used for solar tracking when gears, motors, sensors, and controllers are connected to the array to allow it to move, rotate, follow and track the sun's movement in the sky.

A further advantage is to provide a means of more efficient solar absorption by providing a means of linking that comprises transparent material so that the photovoltaic modules may be arranged without worry of shading the photovoltaic modules.

The present invention provides an array comprising a first photovoltaic module and a second photovoltaic module placed at a distance above the first photovoltaic module, wherein the second photovoltaic module comprises a central hole or cutout. The second photovoltaic module may be in the shape of a ring. In addition, a plurality of photovoltaic modules may be arranged at a distance above and in overlapping relationship to the first photovoltaic module. The vertical distance shall be determined by the distance from the periphery (120, 220) to the closest point on the inner surface (130, 230) of the second photovoltaic module multiplied by 2.5-7.5.

This array allows for both horizontal and vertical expansion. It provides a way to expand length wise, width wise, and height wise, and by nature of this is three-dimensional. By nature of a photovoltaic module that has a central cutout or hole, or is shaped in a ring, light is allowed from both the sides and the hollow middle to shine to the area below it. As you lift a ring from a surface, the higher you lift it, the more light is allowed to shine on the surface below as expressed in FIG. 15. A ring (1501A) creates a darker shadow (1550A) when closer to the surface below it. A ring (1501B) placed higher creates less of a shadow (1550B) when compared to a shadow (1550A) cast by a lower ring (1501A). A ring (1501C) placed even higher creates even less of a shadow (1550C) when compared to the other shadows (1550A, 1550B). By nature of a ring (1601B) placed over another ring (1601A), the shadow (1650) that is cast when light is shown at an angle from a source of illumination (1640), allows for an opposite curved shadow (1650) to fall upon the lower ring as expressed in FIG. 16. This minimizes the percentage of light blockage.

The solar array provided herein provides a more cost effective solution in design and implementation compared to traditional arrays.

### BRIEF DESCRIPTION OF THE DRAWINGS

FIG. 1 Perspective view of a ringed photovoltaic module elevated over a quadrilateral photovoltaic module by means of a central hollow pole.

FIG. 2 Top view of a ringed photovoltaic module linked to a central hollow pole by means of a hollow pole that passes through the central hollow pole and links on both ends to the inner surface of the ringed photovoltaic module.

FIG. 3 Perspective view of three ringed photovoltaic modules linked together by means of a central hollow pole.

FIG. 4 Side view of three ringed photovoltaic modules linked together by means of a central hollow pole where the photovoltaic modules are facing upwards.

FIG. 5 Side view of three ringed photovoltaic modules positioned at an angle linked together by means of a central hollow pole where the photovoltaic modules are facing upwards at a forty five degree angle.

FIG. 6 Side view of three ringed photovoltaic modules linked together by means of a central hollow pole with a light bulb at the top.

FIG. 7 Oblique view of a ringed photovoltaic module elevated over a traditional quadrilateral photovoltaic module by means of a peripheral frame.

FIG. 8 Top view of nine ringed photovoltaic modules linked together by means of a peripheral frame.

FIG. 9 Oblique view of nine ringed photovoltaic modules arranged into a two dimensional grid layer elevated over a traditional quadrilateral photovoltaic module by means of a peripheral frame.

FIG. 10 Oblique view of three levels of nine ringed photovoltaic modules arranged into successive two dimensional grid layers elevated over each other and a traditional quadrilateral photovoltaic module by means of a peripheral frame.

FIG. 11 Side view of three ringed photovoltaic modules positioned above each other at an angle by means of a pole and connectors.

FIG. 12 Top view of eight quadrilateral photovoltaic modules arranged in a ring shape.

FIG. 13 Top view of twenty four quadrilateral photovoltaic modules arranged into an approximately square shape.

FIG. 14 Perspective view of seven ringed photovoltaic modules linked together by means of a central hollow pole.

FIG. 15 Perspective view of three ringed photovoltaic modules placed at different distances above three other ringed photovoltaic modules to provide an example of how the amount of light allowed to shine below a ringed photovoltaic module increases as it is placed further from what it is elevated above.

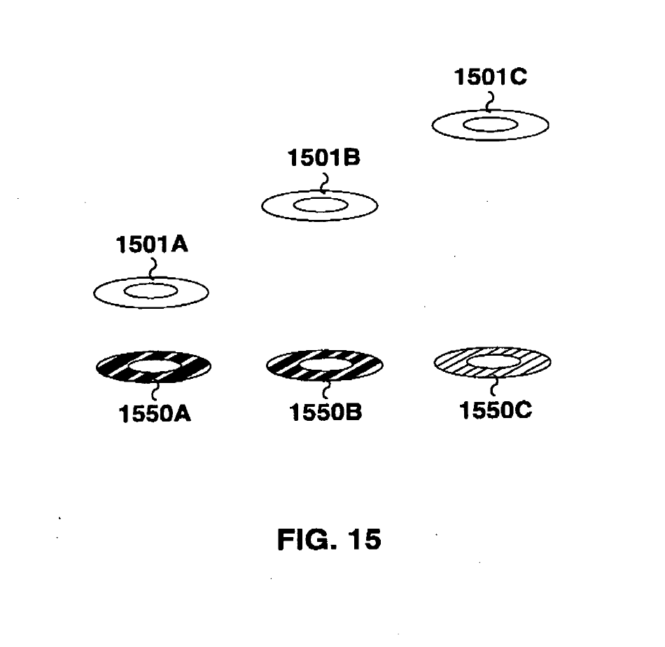

FIG. 16 Perspective view of a ringed photovoltaic module placed at a distance above another ringed photovoltaic module to provide an example of how light shining at an angle on a first ringed photovoltaic module influences the light shining on a second ringed photovoltaic module placed at a distance below the first.

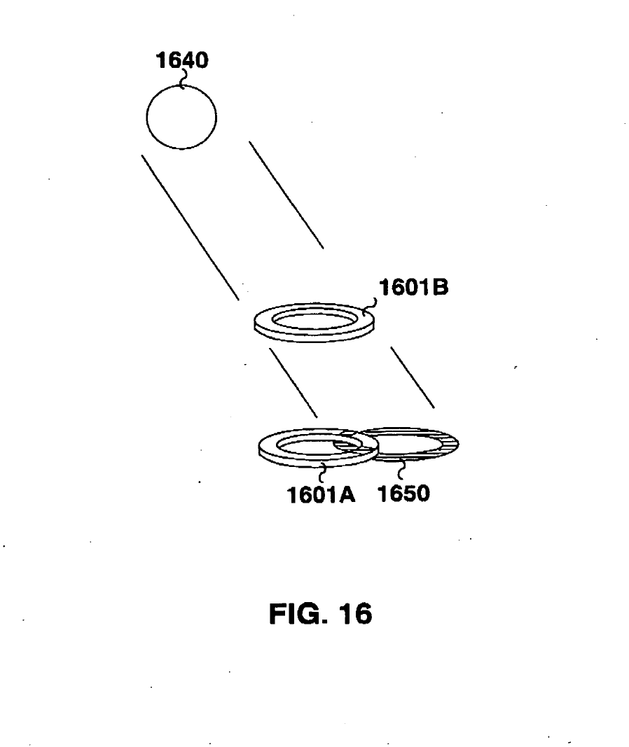

FIG. 17 Top view of seven ringed photovoltaic modules arranged in a circular peripheral frame.

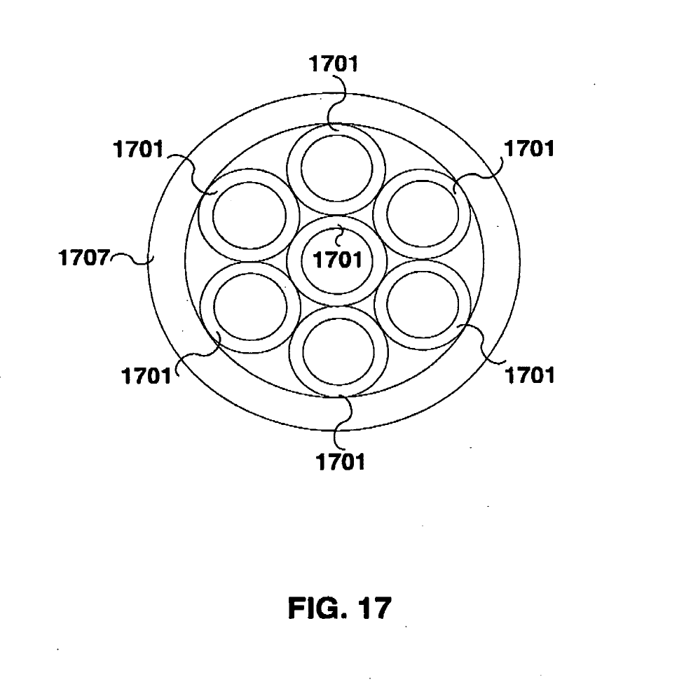

FIG. 18 Top view of a quadrilateral photovoltaic module with a central cutout or hole.

### EMBODIMENTS

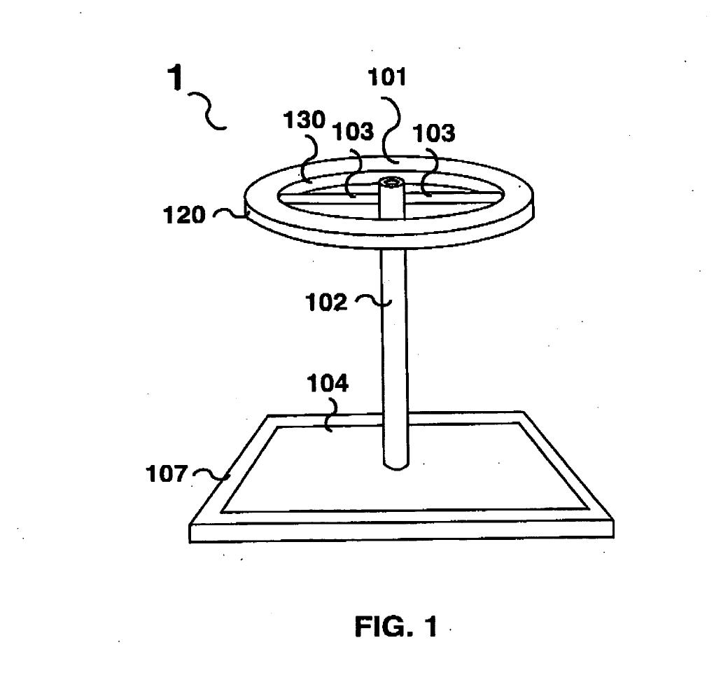

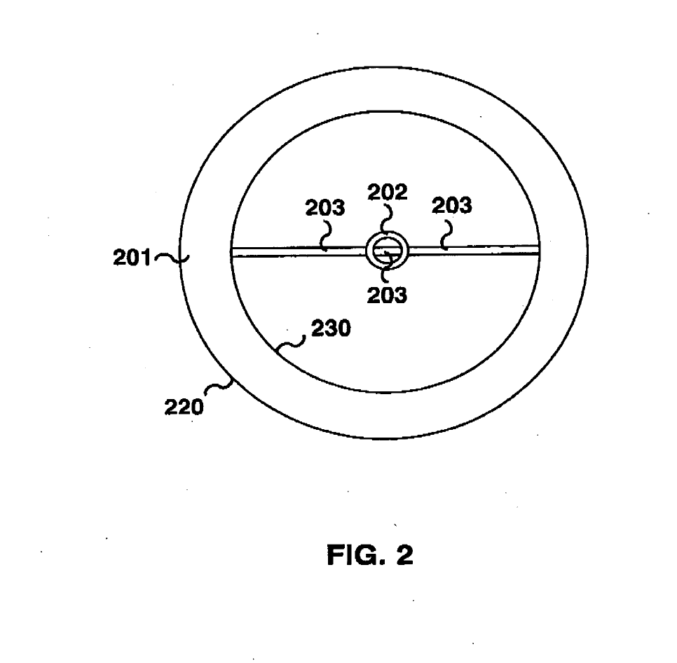

FIGS. 1, 2, 3, 4, 5, and 6 illustrate Embodiment 1 of the array (1) in which the linking mechanism is a pole or central hollow pole (102, 202, 302, 402, 502, 602). Referring to FIG. 1., a second photovoltaic module with a cutout or hole (101) is placed above and in overlapping relationship to a first photovoltaic module (104). In FIG. 1, the second photovoltaic module (101) comprises both a ringed shaped periphery (120) with a cutout or hole which is ring shaped as well (130). The ring shaped photovoltaic module (101) is placed above a quadrilateral shaped photovoltaic module (104) by means of a linking mechanism which is a central pole or hollow pole (102), and a second pole or hollow pole (103) that perpendicularly passes through the central pole or hollow pole (102) so that both ends link to opposite sides of the ringed second photovoltaic module's (101) inner surface (130). The central hollow pole (102) is inserted into a hole in the center of the quadrilateral shaped frame (107) so that the central hollow pole (102) may be held upright.

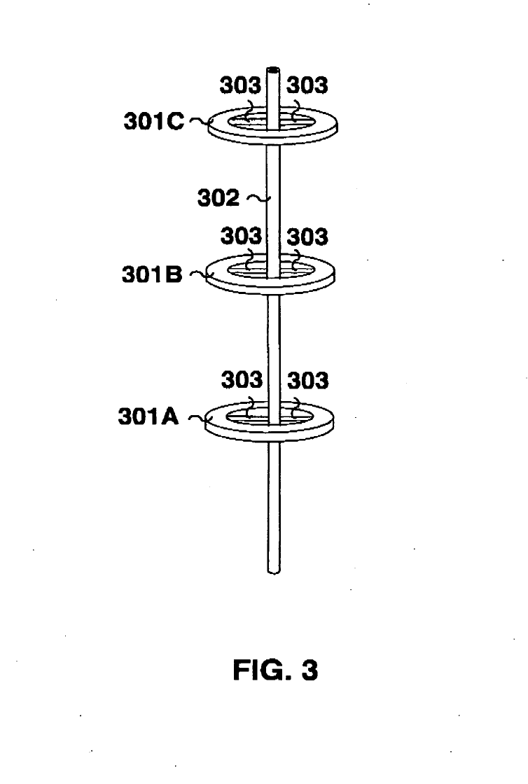

Referring to FIGS. 1-6, the linking mechanism (102, 202, 302, 402, 502, 602) for linking the photovoltaic modules allows for multiple levels of ringed photovoltaic modules (301, 401, 501, 601) to be arranged as disclosed in FIG. 3, where multiple ringed photovoltaic modules (301A, 301B, 301C) are placed at a distance above each other in an overlapping vertical relationship. The vertical distance shall be determined by the distance from the inner surface (130, 230) to the periphery (120, 220) of the second photovoltaic module multiplied by 2.5-7.5.

Referring to FIGS. 1-6, a central pole (102, 202, 302, 402, 502, 602) and a second pole (103, 203, 303) can be made hollow to allow space for electrical wiring when it is deemed beneficial to have the wiring housed within the poles of the array. The central pole (102, 202, 302, 402, 502, 602) and second pole (103, 203, 303) may at times be poles without hollowness when the electrical wiring is deemed more beneficial on the exterior of the linking mechanism. A ringed second photovoltaic module (101, 201, 301, 401, 501, 601) is connected to the central pole or hollow pole (102, 202, 302, 402, 502, 602) by means of second pole or hollow pole (103, 203, 303) that perpendicularly passes through the central pole or hollow pole (102, 202, 302, 402, 502, 602) so that each of the ends links to an opposite side of the inner surface (130, 230) of a ringed second photovoltaic module (101, 201, 301, 401, 501, 601). The second hollow pole (103, 203, 303) is inserted into the central hollow pole (102, 202, 302, 402, 502, 602) so that the middle of the hollow pole (103, 203, 303) is positioned within the hollow area of the central hollow pole (102, 202, 302, 402, 502, 602). The ringed second photovoltaic module (101, 201, 301, 401, 501, 601) is then affixed to both ends of the second hollow pole (103, 203, 303) by means of glue, chemicals, screws, bolts, clamps, protrusions and open slots, or other such means. Both the central pole or hollow pole (102, 202, 302, 402, 502, 602) and the second pole or hollow pole (103, 203, 303) may be made of metal, plastic, wood, or other forms of solid materials, however, materials such as transparent glass and plastic would increase the amount of light energy captured by the photovoltaic modules.

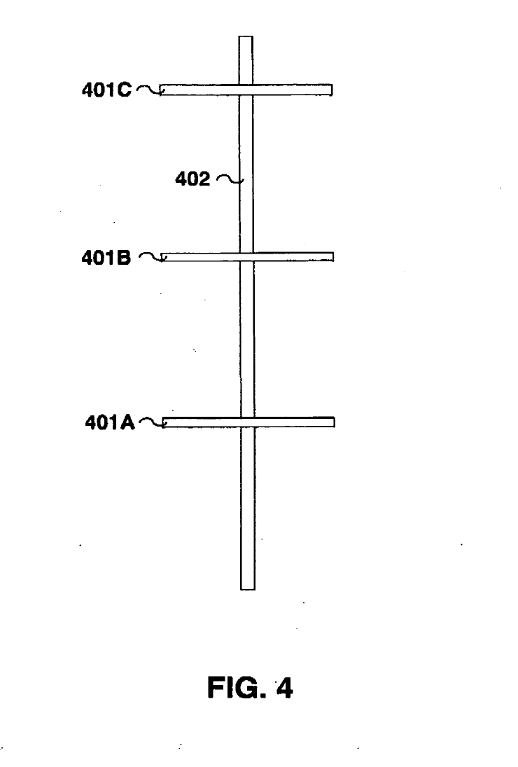

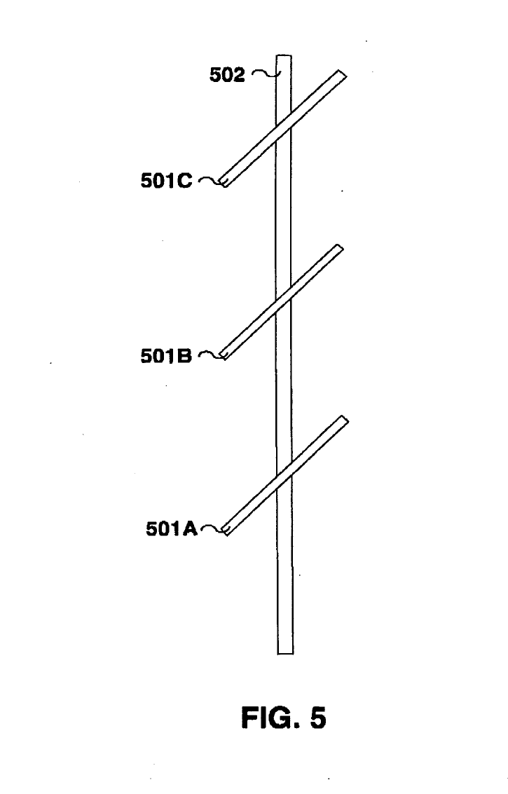

As depicted in FIGS. 4 and 5, the linking mechanism (402 and 502) allows for the rotation of each ringed photovoltaic modules (401A, 401B, and 401C, and 501A, 501B, and 501C). FIG. 4 depicts ringed photovoltaic modules (401A, 401B, and 401C) facing generally upwards, and FIG. 5 depicts the ringed photovoltaic modules (501A, 501B, and 501C) at a different angle after having been rotated. This allows vertical positioning to match the elevation of the sun in the sky.

In addition, by nature of a means of linking comprising a central pole or hollow pole (102, 202, 302, 402, 502, 602), this central pole or hollow pole may be placed upon a means of rotation so that the central pole or hollow pole (102, 202, 302, 402, 502, 602) may rotate 360 degrees along with the ringed photovoltaic modules (101, 201, 301, 401, 501, 601) linked to it. This allows horizontal positioning to match the direction of the sun.

Here follows certain discoveries related to embodiment 1.

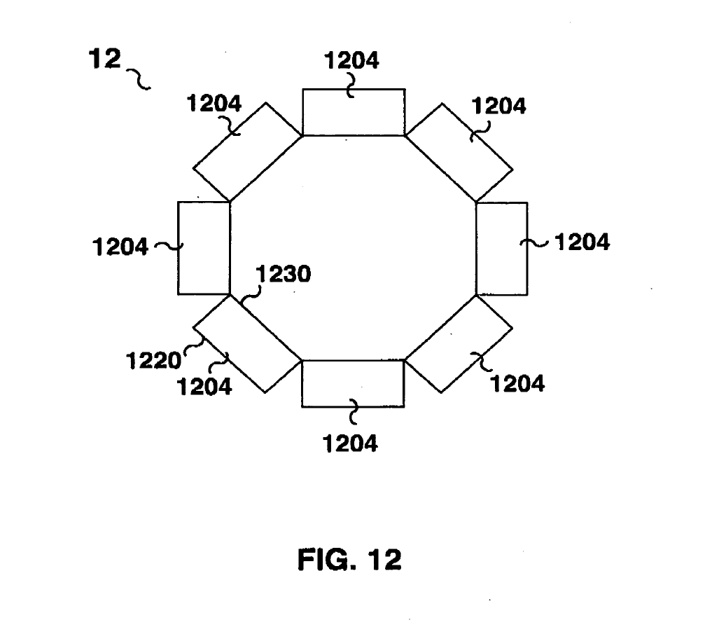

The results of experiments on embodiment 1 proved beneficial technical effects above the traditional configuration tested as a control (FIG. 12). The degree to which results were beneficial was unexpectedly high.

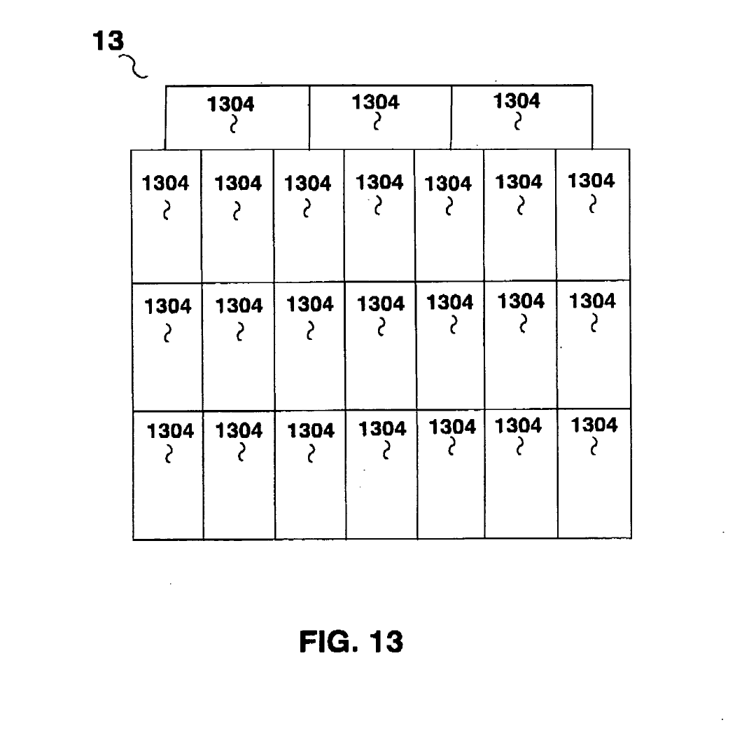

Referring to FIG. 12, using a photovoltaic module measuring 40 mm×20 mm×3 mm with a generated output of 1.5 volts and 60 mA as a base unit, the photovoltaic modules (1204) were configured into a ring of photovoltaic modules (12). The photovoltaic modules used were from [manufacturer [symbol] (A Chinese company translated LianBang) and model number LBT40202]. Eight such photovoltaic modules were configured into a ring shape as disclosed in FIG. 12. For comparison, referring to FIG. 13, the same base unit photovoltaic modules (1304) were used to create an approximately square shaped photovoltaic module configuration (13) as a means to measure the effectiveness of the ringed photovoltaic module array. Twenty four such photovoltaic modules were configured into an approximately square shaped photovoltaic module configuration as disclosed in FIG. 13.

In the first test, a heating light was used. The heating light used was from [manufacturer: NBSS model: 220 volt 245 watt light bulb]. It was placed directly [1 meter] above the photovoltaic modules tested (Where there are multiple levels of grid layers, the top most layer is at a distance of one meter from the source of illumination). All the photovoltaic modules for the ringed photovoltaic module configuration were wired in a series circuit. All the photovoltaic modules for the approximately square photovoltaic module configuration were wired in a series circuit as well. For the experiments a digital multimeter [manufacturer: SZBJ model: BM8320] was used. First, the base unit was tested. The results showed 1.2 volts. Next, the square panel was tested. The results showed 26.2 volts. Next, the ring of photovoltaic modules were tested. The results showed 9.9 volts. Test four involved placing the eight photovoltaic modules configured into a ring shape 150 mm (acting as a second photovoltaic module) above the approximately square photovoltaic module configuration (acting as a first photovoltaic module) so that it was directly in the path of light shining from the heating light towards the approximately square photovoltaic module configuration. The results showed 37.7 volts.

In the next test, seven levels, each comprising eight photovoltaic modules configured into a ringed shape were configured with a transparent vertical pole in the center of the rings. Each level of photovoltaic modules were placed at 150 mm above one another. The results showed 77.5 volts.

The final test using the heating light as the source of illumination involved placing the seven levels of photovoltaic modules configured into ring shapes (12) 150 mm above the photovoltaic modules (1304) configured into an approximately square shaped photovoltaic module configuration (13). The results showed that when added together the voltage was 115 volts. When examined separately, the seven levels of photovoltaic modules configured into a ring shape resulted in the same 77.5 volts as when tested alone. The square panel configuration resulted in 22.5 volts. In combination they resulted 100 volts.

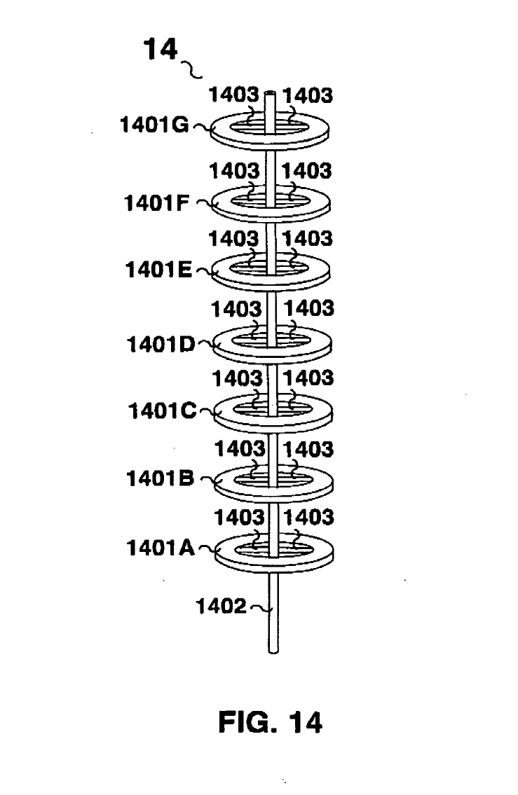

TABLE 1

| Configuration | Distance from source | Power generated |
|---|---|---|
| Single base unit (1204, | 1 meter | 1.2 volts |
| 1304) | | |
| Ringed configuration (12) | 1 meter | 9.9 volts |
| Approximately square | 1 meter | 26.2 volts |
| configuration (13) | | |
| Ringed configuration | 1 meter | 37.7 volts |
| placed above | | |
| approximately square | | |
| configuration (in the | | |
| configuration of FIG. 1) | | |
| Seven levels of ringed | 1 meter | 77.5 volts |
| Configurations (in the | | |
| configuration of FIG. 14) | | |
| Seven levels of ringed | 1 meter | 100 volts |
| configurations (in the | | |
| configuration of FIG. 14) | | |
| placed above the | | |
| approximately square | | |
| configuration (13) | | |

As can be seen in the results of experiments in embodiment 1, the array of the present invention produced beneficial technical effects above the traditional configuration tested as a control. Also, the degree to which results were beneficial was unexpectedly high.

In addition to the first test above, a second test was done to assess the power generation capability of using bring sunlight as the source of illumination. In the second test represented in TABLE 2, all the procedures were the same as the first test represented in TABLE 1, only the source of illumination was changed to bright sunlight shining from above.

TABLE 2

| | | Power |
|---|---|---|
| Configuration | Distance from source | generated |
| Single base unit (1204, | The distance from the sun | 1.6 volts |
| 1304) | | |
| Ringed configuration (12) | The distance from the sun | 12.5 volts |
| Approximately square | The distance from the sun | 38.4 volts |
| configuration (13) | | |
| Ringed configuration | The distance from the sun | 49.4 volts |
| placed above | | |
| approximately square | | |
| configuration (in the | | |
| configuration of FIG. 1) | | |
| Seven levels of ringed | The distance from the sun | 84 volts |
| Configurations (in the | | |
| configuration of FIG. 14) | | |
| Seven levels of ringed | The distance from the sun | 118.1 volts |
| configurations (in the | | |
| configuration of FIG. 14) | | |
| placed above the | | |
| approximately square | | |
| configuration (13) | | |

In addition to the first and second tests represented in TABLE 1 and TABLE 2, a further test was done to determine an ideal vertical distance for the placement of ringed photovoltaic modules (12) when placed directly above each other at a distance.

The distance between ringed photovoltaic modules (12) placed directly above each other effects the electrical generation of a lower ringed photovoltaic module (12) as seen in TABLE 3. Because efficiency in solar absorption per cubic area is important in a three-dimensional array, the vertical distance between successive grid layers of ringed photovoltaic modules (12) is important in determining the total output of electrical generation.

For this test (represented in TABLE 3), the same 220 v 245 w heating light used in the first test (represented in TABLE 1) was used. The distance of the lower ringed photovoltaic module (12) was one meter from the source of illumination, with the upper ringed photovoltaic module (12) being placed at different distances above the lower ringed photovoltaic module (12). Both the upper ringed photovoltaic module (12) and lower ringed photovoltaic module (12) had a diameter of 130 mm, as well as a distance of 20 mm from the periphery (1220) to the nearest point on the inner surface (1230) of each ringed photovoltaic module (12). The upper ringed photovoltaic module (12) was placed at different elevations above the lower base ringed photovoltaic module (12). This was done to test the effect that the upper ringed photovoltaic module's shading of light had on the electrical generation of the lower ringed photovoltaic module (12).

The results in TABLE 3 reveal that the further an upper ringed photovoltaic module (12) is placed above a lower ringed photovoltaic module (12), the closer the lower ringed photovoltaic module's electrical generation comes to matching a ringed photovoltaic module (12) with no effect of shading on it what so ever. The closer the ringed photovoltaic modules (12) are placed together, a greater loss of electrical generation is seen in the electrical generation in the lower ringed photovoltaic module (12) because of more shading from the ringed photovoltaic module (12) above it.

For the sake of efficiency it would seem that the further apart the ringed photovoltaic modules (12) are placed, the more efficient the lower ringed photovoltaic module (12) would be. However, a further cost to factor in is not only the cost of the photovoltaic modules (12), but also the cost of materials to elevate each successive grid layer above each other. The higher the upper ringed photovoltaic module (12) is placed, the more material must be used to elevate that upper ringed photovoltaic module (12). Another consideration is that of the stability of the structure of the ringed photovoltaic module array. The further apart the ringed photovoltaic modules (12) are placed, the more attention must be placed into creating a stable structure in a peripheral frame or other method of linking of the ringed photovoltaic modules (12). For this reason, placing ringed photovoltaic modules (12) at vertical distances where there is a certain amount of loss of electrical generation because of shading from an upper ringed photovoltaic module (12) can be beneficial so long as an overall benefit of electrical output and a benefit in structural stability is achieved.

A distance of 150 mm as seen in Table 3, represents a distance in which there is 10% loss or 90% (of a ringed photovoltaic module (12) without shading) of electrical generation from the lower ringed photovoltaic module (12). This also represents a distance equal to 7.5 times 20 mm, 20 mm being the distance from the periphery (1220) to the nearest point on the inner surface (1230) of a ringed photovoltaic module (12). Considering an upper ringed photovoltaic module (12) will have 100% of possible electrical generation given the source of illumination, a loss of 10% in a lower ringed photovoltaic module (12) would equal 190% (100%+90%=190%) electrical generation when both the upper ringed photovoltaic module (12) and the lower ringed photovoltaic module (12) are added together. This represents 95% of an ideal electrical generation for both ringed photovoltaic modules (12).

A distance of 100 mm as seen in Table 3, represents a distance in which there is 13% loss or 97% (of a ringed photovoltaic module (12) without shading) of electrical generation from the lower ringed photovoltaic module (12). This also represents a distance equal to 5 times 20 mm, 20 mm being the distance from the periphery (1220) to the nearest point on the inner surface (1230) of a ringed photovoltaic module (12). Considering an upper ringed photovoltaic module (12) will have 100% of possible electrical generation given the source of illumination, a loss of 13% in a lower ringed photovoltaic module would equal 187% (100%+87%=187%) electrical generation when both the upper ringed photovoltaic module (12) and the lower ringed photovoltaic module (12) are added together. This represents 93.5% of an ideal electrical generation for both ringed photovoltaic modules (12). Considering an upper ringed photovoltaic module (12) will have 100% of possible electrical generation given the source of illumination, a loss of 10% in a lower ringed photovoltaic module (12) would equal 190% (100%+90%=190%) electrical generation when both the upper ringed photovoltaic module (12) and the lower ringed photovoltaic module (12) are added together. This represents 95% of an ideal electrical generation for both ringed photovoltaic modules (12).

A distance of 50 mm as seen in Table 3, represents a distance in which there is 18% loss or 82% (of a ringed photovoltaic module (12) without shading) of electrical generation from the lower ringed photovoltaic module (12). This also represents a distance equal to 2.5 times 20 mm, 20 mm being the distance from the periphery (1220) to the nearest point on the inner surface (1230) of a ringed photovoltaic module (12). Considering an upper ringed photovoltaic module (12) will have 100% of possible electrical generation given the source of illumination, a loss of 18% in a lower ringed photovoltaic module (12) would equal 182% (100%+82%=182%) electrical generation when both the upper ringed photovoltaic module (12) and the lower ringed photovoltaic module (12) are added together. This represents 91% of an ideal electrical generation for both ringed photovoltaic modules (12).

Using the effects of different vertical distances on the two ringed photovoltaic modules (12) (as represented in TABLE 3) as a reference to determine an ideal vertical distance between ringed photovoltaic modules (12) placed on successive vertical grid layers, an overall generation of power generated from both upper and lower ringed photovoltaic modules (12) equaling 91% to 95% (91% to 95% being 2.5 times to 7.5 times the distance from the periphery (1220) to the nearest point on the inner surface (1230) of a ringed photovoltaic module) is beneficial considering that there is a savings in cost that is incurred from a savings in usage of materials for further elevating the upper ringed photovoltaic module (12).

TABLE 3

| Configuration | Distance from source | Power generated |
|---|---|---|
| A base ringed | 1 meter | 9.9 volts |
| photovoltaic module (12) | | |
| A lower base ringed | 1 meter | 8.2 volts |
| photovoltaic module (12) | | (lower base ring) |
| with an upper ringed | | |
| photovoltaic module (12) | | |
| placed 50 mm above it. | | |
| A lower base ringed | 1 meter | 8.7 volts |
| photovoltaic module (12) | | (lower base ring) |
| with an upper ringed | | |
| photovoltaic module (12) | | |
| placed 100 mm above it. | | |
| A lower base ringed | 1 meter | 9.0 volts |
| photovoltaic module (12) | | (lower base ring) |
| with an upper ringed | | |
| photovoltaic module (12) | | |
| placed 150 mm above it. | | |
| A lower base ringed | 1 meter | 9.3 volts |
| photovoltaic module (12) | | (lower base ring) |
| with an upper ringed | | |
| photovoltaic module (12) | | |
| placed 200 mm above it. | | |
| A lower base ringed | 1 meter | 9.4 volts |
| photovoltaic module (12) | | (lower base ring) |
| with an upper ringed | | |
| photovoltaic module (12) | | |
| placed 250 mm above it. | | |
| A lower base ringed | 1 meter | 9.5 volts |
| photovoltaic module (12) | | (lower base ring) |
| with an upper ringed | | |
| photovoltaic module (12) | | |
| placed 300 mm above it. | | |
| A lower base ringed | 1 meter | 9.6 volts |
| photovoltaic module (12) | | (lower base ring) |
| with an upper ringed | | |
| photovoltaic module (12) | | |
| placed 350 mm above it. | | |
| A lower base ringed | 1 meter | 9.6 volts |
| photovoltaic module (12) | | (lower base ring) |
| with an upper ringed | | |
| photovoltaic module (12) | | |
| placed 400 mm above it. | | |
| A lower base ringed | 1 meter | 9.6 volts |
| photovoltaic module (12) | | (lower base ring) |
| with an upper ringed | | |
| photovoltaic module (12) | | |
| placed 450 mm above it. | | |
| A lower base ringed | 1 meter | 9.6 volts |
| photovoltaic module (12) | | (lower base ring) |
| with an upper ringed | | |
| photovoltaic module (12) | | |
| placed 500 mm above it. | | |
| A lower base ringed | 1 meter | 9.7 volts |
| photovoltaic module (12) | | (lower base ring) |
| with an upper ringed | | |
| photovoltaic module (12) | | |
| placed 800 mm above it. | | |

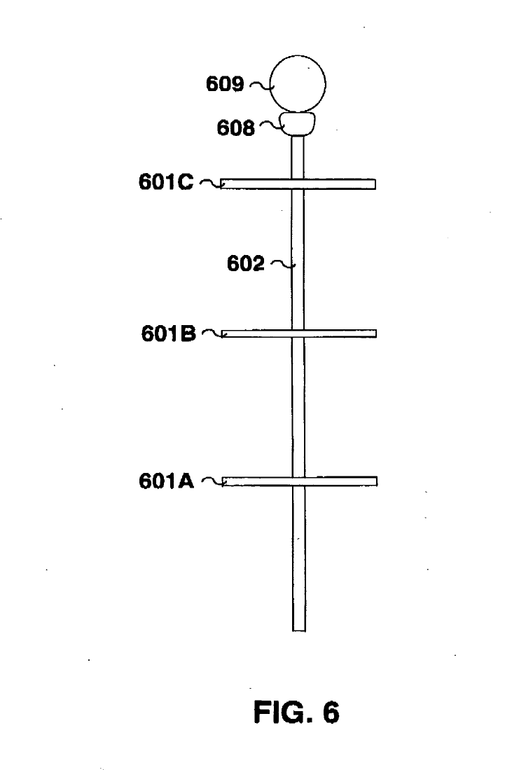

Embodiment 2 is represented in FIG. 6, in which a light bulb (609) is affixed above the highest level of the ringed photovoltaic module (601c). There are three ringed photovoltaic modules (601a, 601b, 603c). Attached to the central pole or hollow pole (602) is a light socket (608). The light bulb (609) is then placed in the light socket (608) so that the light bulb (609), light socket (608) and the central pole or hollow pole (602) are all connected. A light bulb may be positioned directly above the ringed photovoltaic modules at a distance or a light bulb may be positioned in a different position so long as the light shining from the light bulb shines on a light absorbing side of a photovoltaic module with a central cutout or hole.

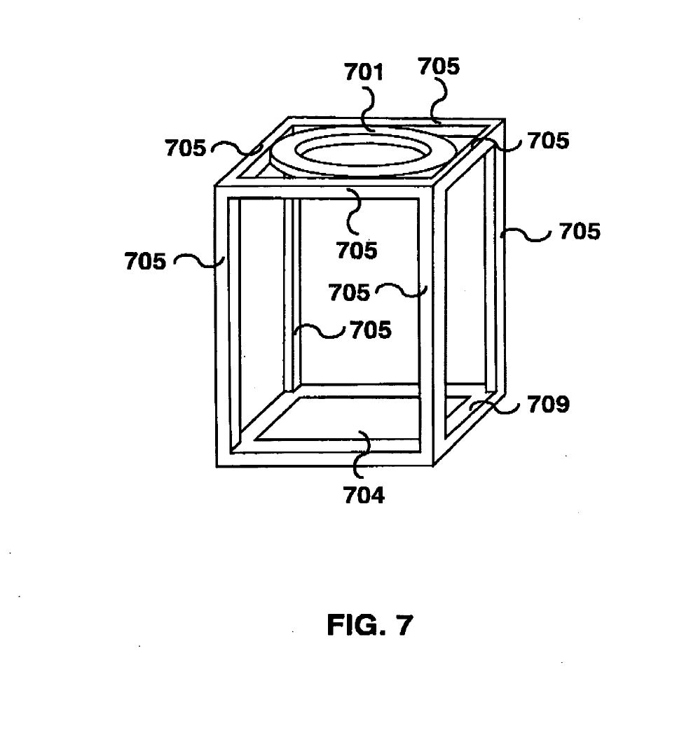

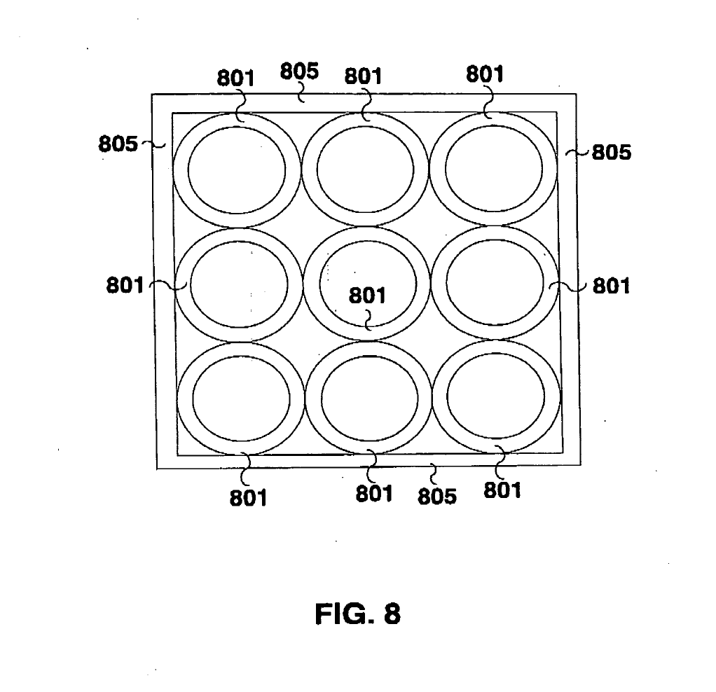

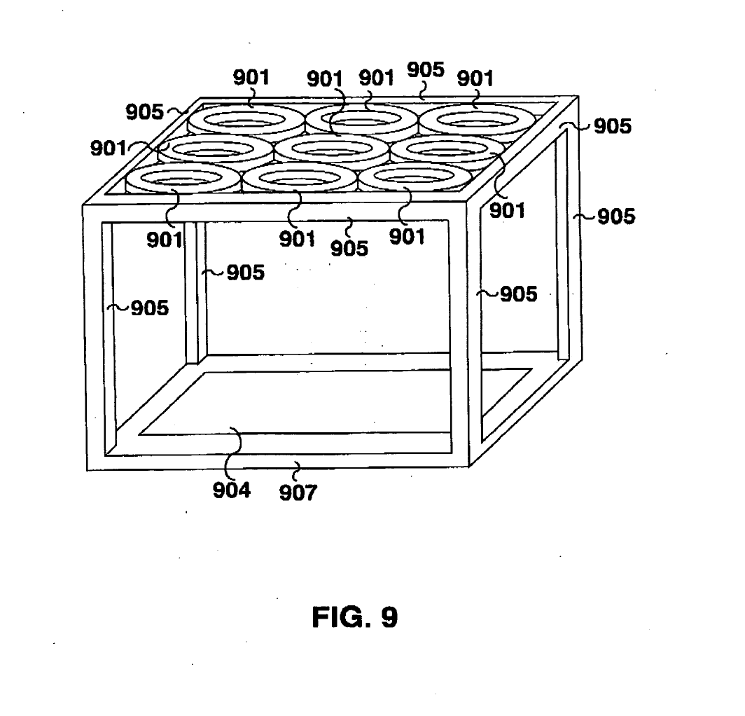

A third embodiment is disclosed in FIGS. 7, 8, 9, and 10, in which a ringed photovoltaic module (701) or multiple rings of photovoltaic modules (801, 901, 1001) are linked and elevated by means of a linking mechanism in the form of a peripheral frame (707, 807, 907, 1007) that consists of beams (705, 805, 905, 1005), or poles (not displayed), or the like.

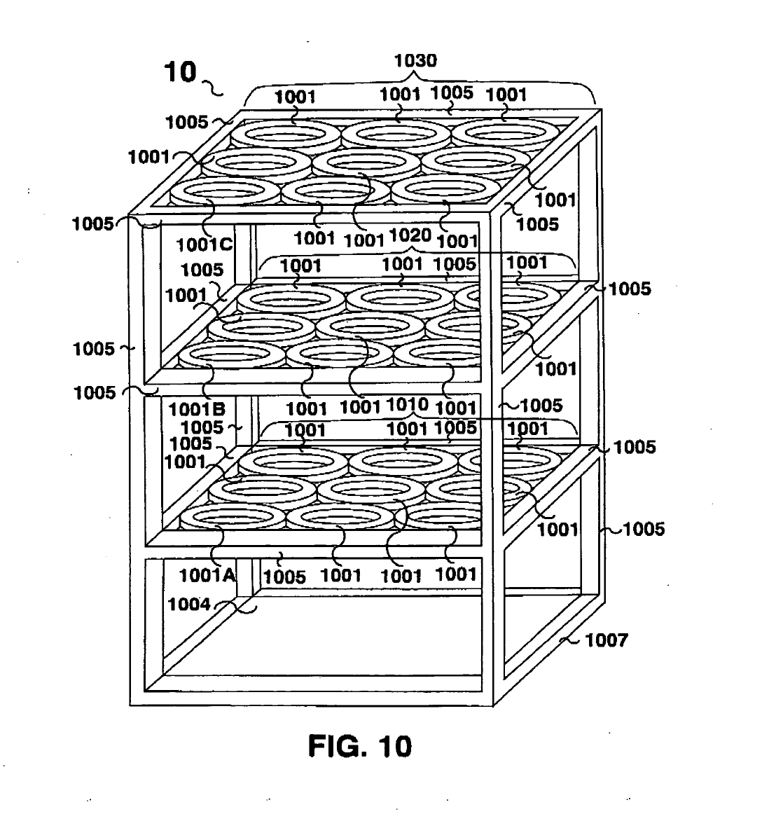

Referring to FIG. 10, a three-dimensional array (10) comprising a base photovoltaic module (1004) and a plurality of photovoltaic modules (1001) arranged into a plurality of successive two dimensional grid layers (1010, 1020, 1030), wherein each two dimensional grid layer (1010, 1020, 1030) is placed a distance above and in overlapping relationship to the base photovoltaic module (1004) or successive two dimensional grid layer (1010, 1020, 1030) below it, wherein each of the photovoltaic modules (1001, 1001A, 1001B, 1001C) in each successive two dimensional grid layer (1010, 1020, 1030) comprises a central hole or cutout and is placed in overlapping relationship to a photovoltaic module in a successive two dimensional grid layer (1010, 1020, 1030) below it.

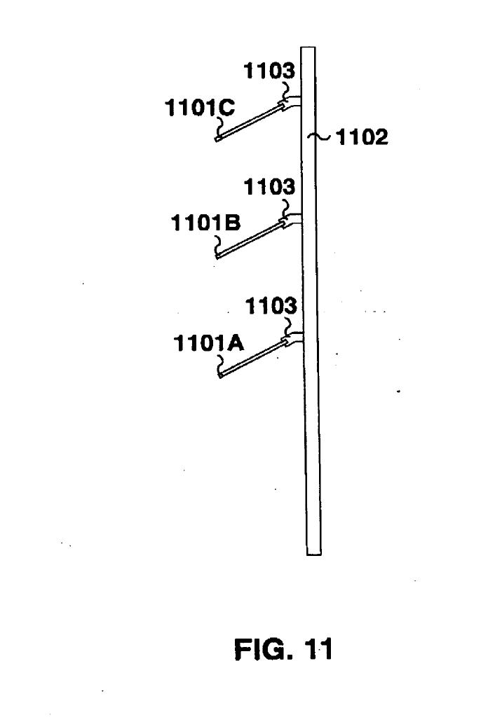

A fourth embodiment is disclosed in FIG. 11, where a ringed or multiple ringed photovoltaic modules (1101A, 1101B, 1101C) are connected through a linking mechanism in the form of a pole (1102) at an angle by means of a clamp like connector (1103) so that all the ringed photovoltaic modules with a cutout or hole (1101A, 1101B, 1101C) are overlapping or offset in a vertical relationship above each other. A simplified adaption of the fourth embodiment that allows the arrangement of photovoltaic modules with a central cutout or hole is a pole (1102), or beam with a perpendicular cutout so that a portion of a ringed photovoltaic module may be inserted into the recess that the cutout provides.

A fifth embodiment is to link all ringed photovoltaic modules (101, 201, 301, 401, 501, 601, 701, 801, 901, 1001, 1101, 1401, 1701) by means of a linking mechanism such as strings, cables, wires, or other such substitutes, so that the top of the array may be connected to a pole perpendicularly connected to a vertical wall, a tree branch, a pole, a structural beam, or any other such means of elevation, so that when the top of the array is connected, the relationship between multiple levels of photovoltaic modules will be elongated to a functional distance for the absorption of solar energy. By nature of gravity, the multiple levels of photovoltaic modules with a cutout or hole will distance themselves from each other to an appropriate position, so that the photovoltaic modules are generally overlapping at a distance.

A sixth embodiment is to link all ringed photovoltaic modules by means of a transparent cylinder with internal protrusions extending inwards to hold the ringed photovoltaic modules in place, when those photovoltaic modules are placed to rest upon these protrusions. Another means of linking the ringed photovoltaic modules to a transparent cylinder is by means of protrusions on the periphery of the ringed photovoltaic modules extending outwards, so that when fit into the holes or cutouts of a transparent cylinder, it is held in place. Alternately a transparent cylinder without protrusions may be used, where the means of linking is either sufficient pressure from the sides of the cylinder to hold the ringed photovoltaic modules in place, screws, bolts, or by means of chemicals, glues, or other such means of bonding.

A seventh embodiment is to substitute a ringed photovoltaic module (101, 201, 301, 401, 501, 601, 701, 801, 901, 1001, 1101, 1401, 1701) in any of the previously disclosed embodiments with traditional quadrilateral shaped photovoltaic modules (104, 704, 904) configured into a ring shape. One possible example of such a configuration is disclosed in FIG. 12 where eight quadrilateral photovoltaic modules (1204) are configured into a ring.

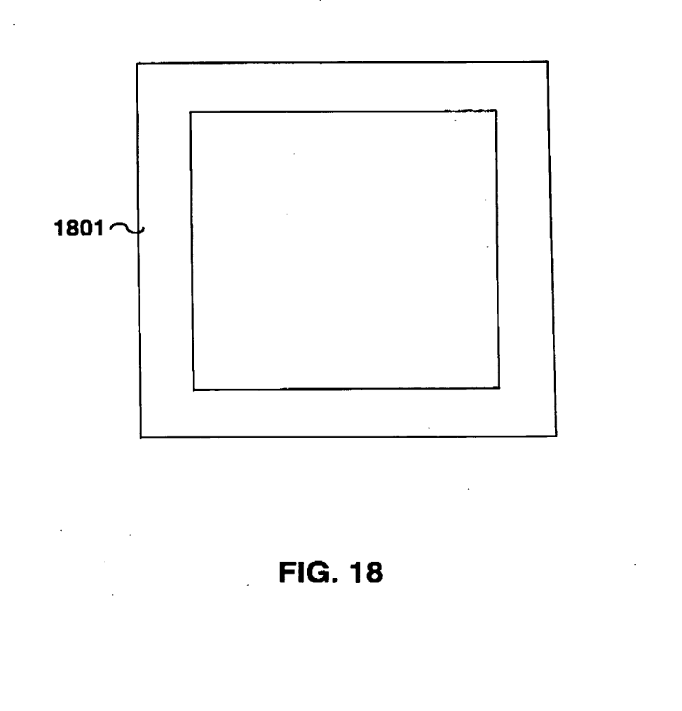

An eighth embodiment is to use the photovoltaic module with a cutout or hole as represented in FIG. 18 in any of embodiments disclosed above, where a corner of the quadrilateral photovoltaic module with a cutout or hole (1801) shall face generally towards the horizontal direction of the sun or source of illumination so that the quadrilateral photovoltaic module with a cutout or hole (1801) is generally parallel to the ground.

This embodiment allows significant amounts of light to reach successive levels of lower photovoltaic modules (1801) when the source of illumination is shining light directly towards a corner of a quadrilateral photovoltaic module with a cutout or hole (1801) from a higher elevated angle. When the light is coming from directly above or from a higher elevated angle directed towards a side of a quadrilateral photovoltaic module with a cutout or hole (1801) the electrical generation is lessened. For this reason a solar tracker is affixed to the array to allow for tracking of the sun, so that a corner may be refocused to match the general direction of the sun or source of illumination at an angle.

A ninth embodiment is to use transparent materials such as glass or plastic in any of the linking materials for all embodiments disclosed above where possible.

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than a restrictive sense. The scope of the invention is to be construed in accordance with the substance defined by the following claims.

I claim:

1. An array comprising a first photovoltaic module and a second photovoltaic module, wherein the second photovoltaic module comprises a central hole or cutout and is placed at a distance above and in an overlapping relationship to the first photovoltaic module.

2. The array of claim 1 wherein the periphery of the second photovoltaic module is ring shaped.

3. The array of claim 2 wherein the central hole or cutout is ring shaped.

4. The array of any of claims 1-3 wherein the distance is a distance from a point on the periphery of the second photovoltaic module to a closest point on an inner surface of the second photovoltaic module multiplied by 2.5-7.5.

5. An array comprising a first photovoltaic module and a plurality of ringed photovoltaic modules arranged at a distance above and in overlapping relationship to the first photovoltaic module or ringed photovoltaic module below it, wherein each ringed photovoltaic module comprises a central cutout or hole.

6. A three-dimensional array comprising a base photovoltaic module and a plurality of photovoltaic modules arranged into a plurality of successive two-dimensional grid layers, wherein each two-dimensional grid layer is placed a distance above and in overlapping relationship to the base photovoltaic module or successive two-dimensional grid layer below it, wherein each of the photovoltaic modules in each successive two-dimensional grid layer comprises a central hole or cutout and is placed in overlapping relationship to a photovoltaic module in a successive two-dimensional grid layer below it.

7. The array of any of claim 1, 2, 3, 5, or 6, further comprising a light bulb positioned at a distance above and in an overlapping or off center vertical relationship to the highest positioned ringed photovoltaic module.

8. The array of any of claim 1, 2, 3, 5, or 6, further comprising a linking mechanism connected to the first photovoltaic module and the second photovoltaic module, wherein the linking mechanism is comprised of transparent material.

9. The array of any of claims 1-3, further comprising a linking mechanism connected to the first photovoltaic module and second photovoltaic module, wherein the linking mechanism is comprised of a central pole and a second pole which comprises a first end and a second end, the central pole is affixed to the first photovoltaic module, the second pole is arranged to pass perpendicularly through a top portion of the central pole, and the first end and second end of the second pole are connected to opposite points on an inner surface of the second photovoltaic module.

10. The array of claim 4 wherein the distance is a distance from a point on the periphery of the second photovoltaic module to a closest point on an inner surface of the second photovoltaic module multiplied by 2.5.

11. The array of claim 4 wherein the distance is a distance from a point on the periphery of the second photovoltaic module to a closest point on an inner surface of the second photovoltaic module multiplied by 5.

12. The array of claim 4 wherein the distance is a distance from a point on the periphery of the second photovoltaic module to a closest point on an inner surface of the second photovoltaic module multiplied by 7.5.

13. The array of any of claims 1-3 wherein the distance is the diameter or the shortest distance from a side to an opposite side of the second photovoltaic module with a central cutout or hole.

14. The array of any of claims 1-3 wherein the distance is half the diameter or half the shortest distance from a side to an opposite side of the second photovoltaic module with a central cutout or hole.
